(19) United States
(12) Patent Application Publication
(10) Pub. No.: US 2012/0070950 A1
(43) Pub. Date: Mar. 22, 2012

(54) Method of Manufacturing a Semiconductor Device

(76) Inventors: Jae-Man Yoon, Gyeonggi-do (KR); Yong-Chul Oh, Gyeonggi-do (KR); Hui-Jung Kim, Seoul (KR); Hyun-Woo Chung, Seoul (KR); Kang-Uk Kim, Seoul (KR)

(21) Appl. No.: 13/306,421

(22) Filed: Nov. 29, 2011

Related U.S. Application Data
(62) Division of application No. 12/236,154, filed on Sep. 23, 2008.

(30) Foreign Application Priority Data
Oct. 8, 2007 (KR) 2007-100728

(51) Int. Cl. H01L 21/8242

(52) U.S. Cl. 438/239; 257/E21.646

(57) ABSTRACT

A semiconductor device includes a substrate having a first area and a second area, a first active structure disposed in the first area, a second active structure disposed in the second area, a first transistor disposed in the first area and a second transistor disposed in the second area. The second active structure may have a height substantially the same as a height of the first active structure. The first transistor includes a first gate structure enclosing an upper portion of the first active structure, a first impurity region formed at a lower portion of the first active structure, and a second impurity region formed at the upper portion of the first active structure. The second transistor includes a second gate structure formed on the second active structure and third impurity regions formed at an upper portion of the second active structure.

### RELATED APPLICATIONS

This application claims priority under 35 U.S.C. §119 to Korean patent Application No. 2007-100728, filed on Oct. 8, 2007 in the Korean Intellectual Property Office (KIPO), the contents of which are herein incorporated by reference in their entirety.

### FIELD OF THE INVENTION

The invention relates to semiconductor devices and methods of manufacturing semiconductor devices. More particularly, the invention relates to semiconductor devices having a vertical channel transistor and a horizontal channel transistor, and methods of manufacturing the semiconductor devices.

### BACKGROUND

In a conventional semiconductor memory device, a transistor generally includes a source region providing charge carriers such as electrons or holes, a drain region consuming the charge carriers, and a gate electrode controlling the flow of charge carriers. When the flow of the charge carriers is adjusted by a voltage applied to the gate electrode, the transistor is referred to as a field effect transistor. This field effect transistor has a channel region between the source region and the drain region. The charge carriers move from the source region to the drain region through the channel region. A gate insulation layer is interposed between the channel region and the gate electrode so as to electrically insulate the channel region from the gate electrode.

Recently, the gate electrodes of transistors have a greatly reduced width as semiconductor memory devices have obtained an extremely high integration degree. When a gate electrode has a minute width, a short channel effect may occur in the transistor. In general, the short channel effect of the transistor may cause various problems with the transistor such as an increase of a leakage current, a decrease of a breakdown voltage, a continuous increase of a current relative to a drain voltage, etc.

Since the short channel effect may be usually caused by a distance decrease between the source region and the drain region, transistors having a recessed channel have been developed to attenuate the short channel effect. For example, Korean Patent No. 589056 discloses a transistor having a gate electrode buried in a recess enlarged as an elliptical shape. A channel region of the transistor has an increased length because the channel region is formed along the buried gate electrode even though the gate electrode has a minute width.

However, transistors including a buried gate electrode may have poor electrical characteristics because a void or a seam is frequently generated in the gate electrode formed in the recess. Further, manufacturing processes for the recess and the buried gate electrode may be somewhat difficult. Therefore, transistors including the buried gate electrode may not have desired electrical characteristics and the productivity of the transistor may decrease.

Considering the above-mentioned problems, transistors having vertically induced channel regions have been suggested. A vertically induced channel region is generated between a source region and a drain region which are vertically disposed relative to a substrate. A transistor having the vertically induced channel region usually includes a fin type active pattern, a column type active pattern, a gate insulation layer enclosing the column type active pattern, a gate electrode on the gate insulation layer, and source/drain regions formed at portions of the active patterns.

Conventional semiconductor memory devices include a transistor having a vertically induced channel region in a cell area of a substrate and a transistor having a horizontally induced channel region in a peripheral area of the substrate. However, manufacturing processes for semiconductor memory devices may be considerably difficult because an active pattern of a transistor having a vertically induced channel region has a structure and a height different from those of an active pattern of the transistor having the horizontally induced channel region. Further, a contact, a plug and/or a capacitor may not be properly formed on a transistor having a vertically induced channel region and/or a transistor having a horizontally induced channel region. As a result, a semiconductor memory device may have poor electrical characteristics and deteriorated integration degree.

### SUMMARY

According to some embodiments, a semiconductor device including a vertical channel transistor and a horizontal channel transistor disposed on one substrate is provided.

According to some embodiments, a method of manufacturing a semiconductor device including a vertical channel transistor and a horizontal channel transistor on one substrate is provided.

According to some embodiments, there is provided a semiconductor device that includes a substrate having a first area and a second area, a first active structure disposed in the first area, a second active structure disposed in the second area, a first transistor disposed in the first area, and a second transistor disposed in the second area. The second active structure may have a height substantially the same as or substantially similar to a height of the first active structure. The first transistor includes a first gate structure enclosing an upper portion of the first active structure, a first impurity region formed at a lower portion of the first active structure, and a second impurity region formed at the upper portion of the first active structure. The second transistor includes a second gate structure formed on the second active structure and third impurity regions formed at an upper portion of the second active structure.

In some embodiments, an epitaxial silicon pattern may be disposed on the second impurity region. Further, a capacitor may be disposed in the first area. The capacitor may be electrically connected to the second impurity region through the epitaxial silicon pattern. Here, the epitaxial silicon pattern may have an area substantially larger than an area of the second impurity region.

In some embodiments, the upper portion of the first active structure may have a fin shape and the lower portion of the first active structure may have a circular pillar shape or a polygonal pillar shape.

In some embodiments, the upper portion of the first active structure may have a width substantially smaller than a width of the lower portion of the first active structure. The first active structure may further include a central portion having a width larger than the width of the upper portion and smaller than the width of the lower portion.

In some embodiments, a first field isolation layer pattern may be disposed between adjacent first active structures, and a second field isolation layer pattern may be disposed between adjacent second active structures. The first field isolation layer pattern may have an upper portion protruded from the lower portion of the first active structure.

In some embodiments, the second field isolation layer pattern may have a height substantially the same as or substantially similar to that of the second active structure.

In some embodiments, the first gate structure may include a first gate insulation layer pattern disposed on a side of the upper portion of the first active structure, and a first conductive layer pattern disposed on the first gate insulation layer pattern. The first conductive layer pattern may further include a first portion enclosing the upper portion of the first active structure, and a second portion extending from the first portion.

In some embodiments, the second gate structure may include a second gate insulation layer pattern disposed on the upper portion of the second active structure, and a second conductive layer pattern disposed on the second gate insulation layer pattern.

According to other embodiments, a method of manufacturing a semiconductor device is provided. A first active structure and a second active structure are formed by partially etching a substrate having a first area and a second area. The first active structure may have a height substantially the same as or substantially similar to a height of the second active structure. A first transistor is formed in the first area. The first transistor includes a first gate structure enclosing an upper portion of the first active structure, a first impurity region formed at a lower portion of the first active structure, and a second impurity region formed at the upper portion of the first active structure. A second transistor is formed in the second area. The second transistor includes a second gate structure formed on the second active structure and third impurity regions formed at an upper portion of the second active structure.

In some embodiments, an epitaxial silicon pattern may be formed on the second impurity region by a selective epitaxial growth process. Further, a capacitor may be formed in the first area. The capacitor may have a lower electrode making contact with the epitaxial silicon pattern.

In the formations of the first and the second active structures according to some embodiments, a first mask may be formed in the first area and a second mask may be formed in the second area. The first mask may have a rectangular structure and the second mask may have a bar or a line structure extending along a first direction. The substrate may be partially etched using the first and the second mask as etching masks, to form a preliminary first active structure and a preliminary second active structure. A third mask may be formed to enclose the preliminary first active structure. The third mask may extend along the first direction. The substrate may be partially etched using the second and the third masks as etching masks, to form the first active structure and the second active structure. In some embodiments, a preliminary first impurity region may be formed at a portion of the substrate between adjacent first active structures before forming the third mask.

In the formation of the first transistor according to some embodiments, a first gate insulation layer may be formed on the preliminary first impurity region and a side of the upper portion of the first active structure. A first conductive layer may be formed on the first gate insulation layer to cover the first active structure. Then, the first conductive layer, the first gate insulation layer and the preliminary first impurity region may be partially etched.

In some embodiments, an isolation layer may be formed on the substrate to cover the first active structure and the second active structure, and the field isolation layer may be partially removed to form a first field isolation layer pattern in the first area and a second field isolation layer pattern in the second area. The first field isolation layer pattern may have a height substantially smaller to the height of the first active structure.

In the formation of the second gate structure according to some embodiments, a second gate insulation layer may be formed on the second active structure, and a second conductive layer may be formed on the second gate insulation layer. Then, the second conductive layer and the second gate insulation layer may be etched.

According to some embodiments, the first active structure on which a vertical channel transistor is formed may have the height substantially the same or substantially similar to the height of the second active structure where a horizontal channel transistor is provided. Hence, upper structures such as a pad, a contact, a wiring and/or a capacitor may be easily formed on the first and the second active structures without any step or any failure of the pad, the contact, the wiring and/or the capacitor. Additionally, the epitaxial silicon pattern may be provided between the vertical channel transistor and one of the upper structures so that a contact resistance between the vertical channel transistor and the upper structure may be reduced and an electrical connection between the vertical channel transistor and the upper structure may be enhanced. Furthermore, the second active structure may have an increased height such that impurities in the third impurity regions may not move to adjacent third impurity regions.

### BRIEF DESCRIPTION OF THE DRAWINGS

Embodiments will become more apparent by describing in detailed thereof with reference to the accompanying drawings, in which:

FIG. 1 is a plan view illustrating a semiconductor device in accordance with some embodiments;

FIG. 2 is a cross-sectional view illustrating the semiconductor device of FIG. 1, taken along line I-II;

FIG. 3 is a cross-sectional view illustrating the semiconductor device of FIG. 1, taken along line III-IV;

FIG. 4 is a cross-sectional view illustrating the semiconductor device of FIG. 1, taken along line V-VI;

FIGS. 5 and 6 are cross-sectional views illustrating a semiconductor device in accordance with some embodiments;

FIGS. 7 and 8 are cross-sectional views illustrating a semiconductor device in accordance with some embodiments; and

FIGS. 9 to 40 are cross-sectional views illustrating a method of manufacturing a semiconductor device in accordance with some embodiments.

### DESCRIPTION OF EMBODIMENTS

Exemplary embodiments are described more fully hereinafter with reference to the accompanying drawings. The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular examplary embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of illustratively idealized embodiments (and intermediate structures) of the invention. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

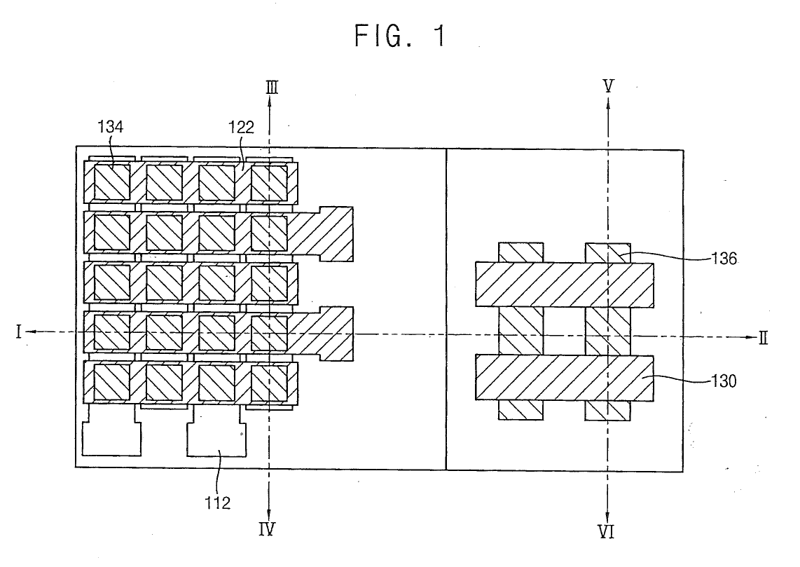

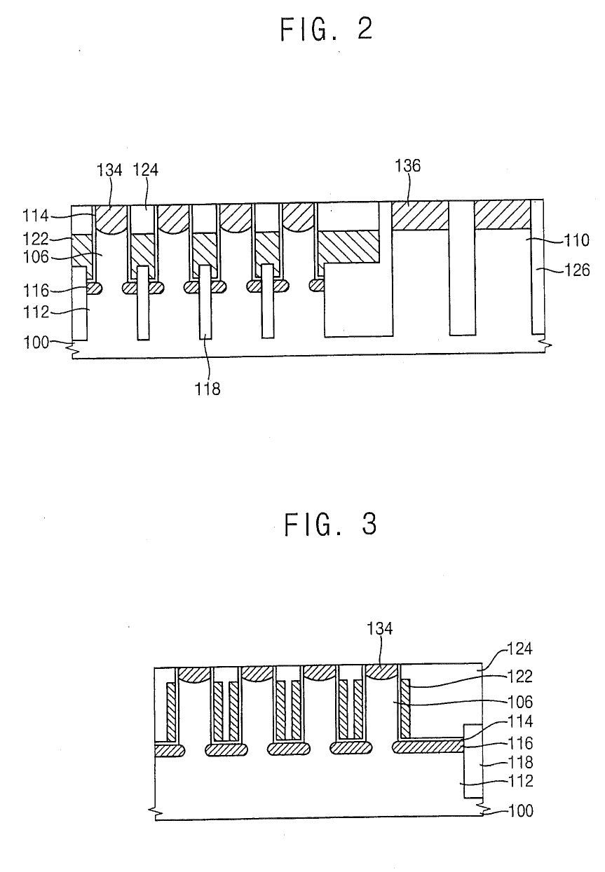

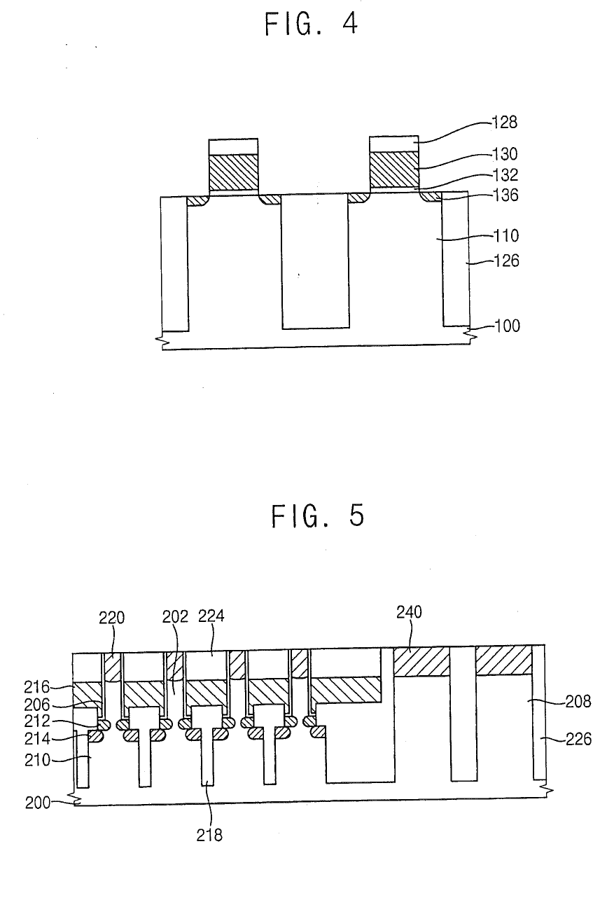

FIG. 1 is a plan view illustrating a semiconductor device in accordance with some embodiments, and FIG. 2 is a cross-sectional view illustrating the semiconductor device of FIG. 1, taken along line FIG. 3 is a cross-sectional view illustrating the semiconductor device of FIG. 1, taken along line and FIG. 4 is a cross-sectional view illustrating the semiconductor device of FIG. 1, taken along line V-VI.

Referring to FIGS. 1 to 4, the illustrated semiconductor device includes a substrate 100 having a first area and a second area, first transistors formed in the first area of the substrate 100, and second transistors disposed in the second area of the substrate 100.

The substrate 100 may include a semiconductor substrate, for example, a silicon substrate, a germanium substrate, a silicon germanium substrate, etc. Alternatively, the substrate 100 may include a silicon-on-insulator (SOI) substrate, a germanium-on-insulator (GOI) substrate, etc. In some embodiments, the substrate 100 may be divided into the first area and the second area. The first area may include a cell area on which memory cells of the semiconductor device are provided. The second area may include a peripheral area where logic circuits are positioned.

First active structures are provided in the first area of the substrate 100, and second active structures 110 are positioned in the second area of the substrate 100. Each of the first active structures and the second active structures 110 may include a material substantially the same as or substantially similar to that of the substrate 100. For example, each of the first active structures and the second active structures 110 may include silicon, germanium, silicon-germanium, etc.

Each of the first active structures in the first area includes an upper portion 106 and a lower portion 112. The lower portion 112 of the first active structure may extend on the substrate 100 in the first area along a first direction. The upper portion 106 of the first active structure may be prolonged on the substrate 100 in a second direction substantially perpendicular to the first direction. In some embodiments, the upper portion 106 of the first active structure may have a fin shape, and the lower portion 112 of the first active structure may have a circular pillar shape or a polygonal pillar shape. The lower portion 112 of the first active structure may have a width substantially larger than a width of the upper portion 106 of the first active structure.

In some embodiments, the first active structures may have various constructions, and the first transistors in the first area may also have various structures in accordance with the constructions of the first active structures.

A first field isolation layer pattern 118 is disposed between adjacent first active structures in the first area. The first field isolation layer pattern 118 may electrically insulate the first active structure from an adjacent first active structure. The first field isolation layer pattern 118 may include an oxide such as silicon oxide. For example, the first field isolation layer pattern 118 may include undoped silicate glass (USG), spin on glass (SOG), born-phosphor silicate glass (BPSG), phosphor silicate glass (PSG), flowable oxide (FOX), fluorosilicate glass (FSG), tonen silazene (TOSZ), tetraethyl ortho silicate (TEOS), plasma enhanced-tetraethyl ortho silicate (PE-TEOS), high density plasma-chemical vapor deposition (HDP-CVD) oxide, etc.

In some embodiments, the first field isolation layer pattern 118 may have a height substantially larger than a height of the lower portion 112 of the first active structure, whereas the height of the first field isolation layer pattern 118 may be substantially smaller than a height of the upper portion 106 of the first active structure. Hence, an upper face of the first isolation layer pattern 118 may exist between an upper face of the lower portion 112 of the first active structure and an upper face of the upper portion 106 of the first active structure. Additionally, the first field isolation layer pattern 118 may have an upper portion protruding from the substrate 100 along a substantially upward direction. Thus, the upper portion of the first field isolation layer pattern 118 may be spaced apart from the upper portion 106 of the first active structure. That is, a gap (not illustrated) is provided between the upper portion of the first field isolation layer pattern 118 and the upper portion 106 of the first active structure.

The second active structures 110 are located in the second area of the substrate 100. Each of the second active structures 110 may have a circular pillar shape or a polygonal pillar shape. Further, the second active structures 110 may have bar shapes or line shapes extending on the substrate 100. The second active structures 110 may extend on the substrate 100 along the first direction. Each of the second active structures 110 includes a lower portion and an upper portion having a width substantially the same as that of the lower portion. Additionally, the lower portion of the second active structure 100 may have a width substantially larger than or substantially similar to that of the lower portion 112 of the first active structure.

In some embodiments, the second active structures 110 may have heights substantially the same as or substantially similar to those of the first active structures. Namely, upper faces of the second active structures 110 and the first active structures may be on the same plane.

A second field isolation layer pattern 126 locates between adjacent second active structures 110. The second field isolation layer pattern 126 may have a height substantially the same as or substantially similar to those of the second active structures 110. The second field isolation layer pattern 126 may include an oxide such as silicon oxide. For example, the second field isolation layer pattern 126 may include USG, SOG, BPSG, PSG, TEOS, PE-TEOS, FOX, FSG, TOSZ, HDP-CVD oxide, etc. In some embodiments, the second field isolation layer pattern 126 may include an oxide substantially the same as or substantially similar to that of the first field isolation layer pattern 118. Alternatively, the first field isolation layer pattern 118 may include an oxide different from that of the second field isolation layer pattern 126.

The first transistors are provided in the first area of the substrate 100. Each of the first transistors includes a first gate structure, a first impurity region 116 and a second impurity region 134. The first gate structure includes a first gate insulation layer pattern 114 and a first conductive layer pattern 122.

The first gate insulation layer pattern 114 is located on a sidewall of the upper portion 106 of the first active structure. Further, the first gate insulation layer pattern 114 is disposed on a peripheral upper face of the lower portion 112 of the first active structure. Thus, the first gate insulation layer pattern 114 may enclose the upper portion 106 of the first active structure. The first gate insulation layer pattern 114 may electrically insulate the first active structure from the first conductive layer pattern 122. In some embodiments, the first gate insulation layer pattern 114 may include silicon oxide formed by a thermal oxidation process or a chemical vapor deposition (CVD) process. Alternatively, the first gate insulation layer pattern 114 may include a metal oxide having a high dielectric constant, for example, hafnium oxide (HfOx), zirconium oxide (ZrOx), tantalum oxide (TaOx), aluminum oxide (AlOx), etc. The first gate insulation layer pattern 114 may be formed by an atomic layer deposition (ALD) process, a CVD process, a sputtering process, an evaporation process, etc.

The first conductive layer pattern 122 is positioned on the first gate insulation layer pattern 114 and the first field isolation layer pattern 118. The first conductive layer pattern 122 may enclose the upper portion 106 of the first active structure. The first conductive layer pattern 122 may extend between adjacent first active structures along the second direction. Here, the first conductive layer pattern 122 may fill the gap around the protruding upper portion of the first field isolation layer pattern 118. The first conductive layer pattern 122 may include polysilicon, a metal and/or a metal compound. For example, the first conductive layer pattern 122 may include polysilicon doped with impurities, tungsten (W), titanium (Ti), aluminum (Al), tantalum (Ta), tungsten nitride (WNx), aluminum nitride (AlNx), titanium nitride (TiNx), titanium aluminum nitride (TiAlxNy), tantalum nitride (TaNx), etc. These may be used along or in a mixture thereof.

In some embodiments, the first conductive layer pattern 122 includes a first portion and a second portion having a width substantially smaller than a width of the first portion. The first portion of the first conductive layer pattern 122 may enclose the upper portion 106 of the first active structure and the second portion of the first conductive layer pattern 122 may extend along the second direction as illustrated in FIGS. 2 and 3. The first portion of the first conductive layer pattern 122 may serve as a gate electrode of the first transistor, and the second portion of the first conductive layer pattern 122 may function as a word line of a semiconductor device. However, the first conductive layer pattern 122 may have a structure varied in accordance with the construction of the first active structure.

In some embodiments, as illustrated in FIGS. 2 and 3, the first portion of the first conductive layer pattern 122 may make a contact with the upper portion 106 of the first active structure and the second portion of the first conductive layer pattern 122 may make contact with the first field isolation layer pattern 118 because the first active structure has the upper portion 106 and the lower portion 112. The protruding upper portion of the first field isolation layer pattern 118 may be buried in the second portion of the first conductive layer pattern 122. The first conductive layer pattern 122 may have a height substantially lower than the height of the first active structure. Hence, an upper face of the first conductive layer pattern 122 may exist below the upper face of the first active structure.

The first impurity region 116 and the second impurity region 134 may serve as source/drain regions of the first transistor, respectively. The first impurity region 116 is disposed at the lower portion 112 of the first active structure, and the second impurity region 134 is positioned at the upper portion 106 of the first active structure. Therefore, a channel region of the first transistor may be generated between the first and the second impurity regions 116 and 134 along a substantially vertical direction relative to the substrate 100.

In some embodiments, the first impurity region 116 may extend along the first direction such as the lower portion 112 of the first active structure. When the first impurity region 116 is prolonged along the first direction, the first impurity region 116 may further serve as a bit line of the semiconductor device. However, the first impurity region 116 may have various positions and structures in accordance with the construction of the first conductive layer pattern 122 and/or the construction of the first active structure.

In some embodiments, as illustrated in FIGS. 2 and 3, the first impurity region 116 may be formed at a peripheral surface of the lower portion 112 of the first active structure. The first gate insulation layer pattern 114 may cover the first impurity region 116. In other words, the first impurity region 116 may be disposed at a connection portion between the upper portion 106 and the lower portion 112 of the first active structure. Adjacent first impurity regions 116 may be insulated by the first field isolation layer pattern 118. Thus, the first impurity region 116 may serve as one of the source/drain regions of a first transistor and further serve as the bit line of a semiconductor device.

The second impurity region 134 is formed at a surface of the upper portion 106 of the first active structure. The second impurity region 134 may serve as the other of the source/drain regions of the first transistor. When the upper portion 106 of the first active structure extends along the second direction, the second impurity region 134 may also extend in the second direction.

In some embodiments, the second impurity region 134 may include a first sub-region and a second sub-region. The first sub-region of the second impurity region 134 may have a relatively high impurity concentration, whereas the second sub-region of the second impurity region 134 may have a relatively low impurity concentration. The first sub-region of the second impurity region 134 may be formed at a peripheral surface of the upper portion 106 of the first active structure, and the second sub-region of the second impurity region 134 may be positioned at a central surface of the upper portion 106 of the first active structure.

As described above, a first transistor may have the channel region generated along the upper portion 106 of the first active structure because the first and the second impurity regions 116 and 134 are provided at the lower and the upper portions 112 and 106 of the first active structure. That is, the channel region of the first transistor may be formed between the first impurity region 116 and the second impurity region 134 along the direction substantially perpendicular to the substrate 100. Hence, the first transistor may be referred to as a vertical channel transistor.

An insulation interlayer 124 is provided on the first conductive layer pattern 122. The upper face of the first active structure and an upper face of the insulation interlayer 124 may exist on substantially the same plane. That is, a total height of the first conductive layer pattern 122 and the insulation interlayer 124 may be substantially the same as or substantially similar to the height of the upper portion 106 of the first active structure. The insulation interlayer 124 may include an oxide such as silicon oxide. For example, the insulation interlayer 124 may include BPSG, PSG, SOG, USG, FOX, FSG, TOSZ, TEOS, PE-TEOS, HDP-CVD oxide etc.

The second transistors are positioned on the second active structures 110 in the second area of the substrate 100. Each of the second transistors includes a second gate structure and third impurity regions 136. The second gate structure includes a second gate insulation layer pattern 132 and a second conductive layer pattern 130.

The second gate insulation layer pattern 132 is disposed on the second active structure 110. The second gate insulation layer pattern 132 electrically insulates the second conductive layer pattern 130 from the second active structure 110. The second gate insulation layer pattern 132 may include an oxide or a metal oxide having a high dielectric constant. For example, the second gate insulation layer pattern 132 may include silicon oxide, hafnium oxide, zirconium oxide, aluminum oxide, tantalum oxide, etc.

The second conductive layer pattern 130 is located on the second gate insulation layer pattern 132. The second conductive layer pattern 130 may serve as a gate electrode of the second transistor. The second conductive layer pattern 130 may extend along the second direction substantially perpendicular to that of the second active structure 110. Hence, the second conductive layer pattern 130 may further serve as a word line of the semiconductor device.

In some embodiments, the second conductive layer pattern 130 may include polysilicon, a metal and/or a metal compound. For example, the second conductive layer pattern 130 may include polysilicon doped with impurities, titanium, aluminum, tungsten, tantalum, tungsten nitride, titanium nitride, tantalum nitride, etc. These may be used alone or in a mixture thereof.

Each of the second transistors further includes a gate mask 128 provided on the second conductive layer pattern 130. The gate mask 128 may electrically insulate the second conductive layer pattern 130 from a plug, a conductive pattern, a contact and/or a wiring formed in the second area. Additionally, the gate mask 128 may serve as an etching mask for forming the second gate structure. The gate mask 128 may include a nitride such as silicon nitride or an oxynitride such as silicon oxynitride.

The third impurity regions 136 are formed at portions of the second active structure 110 adjacent to the second conductive layer pattern 130. For example, the third impurity regions 136 may be positioned at upper peripheral portion of the second active structure 110. The third impurity regions 136 may serve as source/drain regions of the second transistor. However, the third impurity regions 136 may not function as a bit line of the semiconductor device.

In some embodiments, a channel region of the second transistor may be generated between the third impurity regions 136 under the second conductive layer pattern 130 because the third impurity regions 136 are provided at the portions of the second active structure 110 around the second conductive layer pattern 130. That is, the channel region of the second transistor may be formed at a portion of the second active structure 110 beneath the second gate insulation layer pattern 132 along a direction substantially parallel to the substrate 100. Thus, the second transistor may be referred to as a horizontal channel transistor.

In some embodiments, an epitaxial silicon pattern (not illustrated) is provided on the second impurity region 134 of the first transistor. The epitaxial silicon pattern may have an area substantially wider than that of the second impurity region 134. Thus, the epitaxial silicon pattern may cover the second impurity region 134, an end portion of the first gate insulation layer pattern 114 and a portion of the insulation interlayer 124.

According to some embodiments, the first active structure may have heights substantially the same as or substantially similar to heights of the second active structures, so that the second impurity region of the first transistor and the third impurity regions of the second transistor may substantially exist on the same plane. Hence, upper structures such as a conductive pattern, a contact, a plug, a wiring and/or a capacitor may be easily formed on the first transistor and/or the second transistors without any failure or any step among the first transistor, the second transistor and the upper structure such as the conductive pattern, the contact, the plug, the wiring and/or the capacitor. Further, the epitaxial silicon pattern may be formed between the second impurity region and the upper structure, such that a contact resistance between the first transistor and the upper structure may be decreased and also an electrical connection between the first transistor and the upper structure may be improved. As a result, the semiconductor device including the vertical channel transistor and the horizontal channel transistor may have improved electrical characteristics and enhanced reliability.

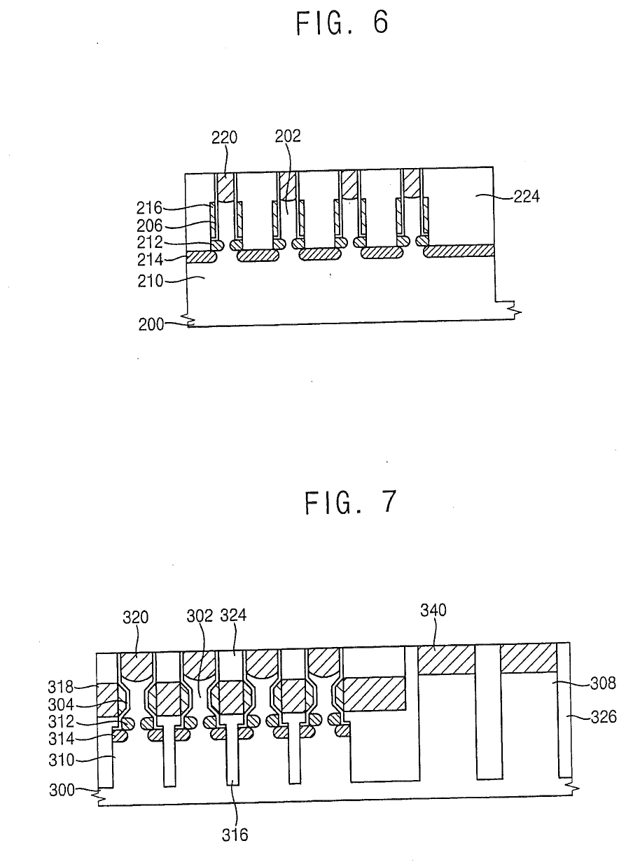

FIGS. 5 and 6 are cross-sectional views illustrating a semiconductor device in accordance with some embodiments.

Referring to FIGS. 5 and 6, the semiconductor device includes a substrate 200, first active structures, second active structures 208, first transistors and second transistors.

The substrate 200 has a first area and a second area. The substrate 200 may include a semiconductor substrate, an SOI substrate, a GOI substrate, etc. The first active structures and the first transistors are disposed in the first area of the substrate 200, and the second active structures 208 and the second transistors are positioned in the second area of the substrate 200.

Each of the first active structures includes an upper portion 202, a central portion and a lower portion 210. The first active structure may include a material substantially the same as or substantially similar to that of the, substrate 200. The lower portion 210 of the first active structure may have a width substantially larger than a width of the central portion thereof, and the upper portion 202 of the first active structure may have a width substantially smaller than the width of the central portion of the first active structure. Thus, the first active structure may have a construction including two steps.

A first field isolation layer pattern 218 is positioned in the first area between adjacent first active structures. The first field isolation layer pattern 218 has a lower portion and an upper portion having a width larger than a width of the lower portion thereof. For example, the upper portion of the first field isolation layer pattern 218 may have a rectangular cross-section. The first field isolation layer pattern 218 may separate the first active structure from adjacent first active structure. The first field isolation layer pattern 218 may include an oxide such as silicon oxide.

In some embodiments, the first field isolation layer pattern 218 may have a height substantially larger than a height of the lower portion 210 of the first active structure, whereas the height of the first field isolation layer pattern 218 may be substantially smaller than an upper portion 202 of the first active structure. The upper portion of the first field isolation layer pattern 218 may be partially protruded, so that a gap may be provided between the upper portion of the first field isolation layer pattern 218 and the upper portion 202 of the first active structure.

The second active structures 208 in the second area may have widths substantially similar to or substantially larger than the widths of the lower portions 210 of the first active structures. A second field isolation layer pattern 226 is provided between adjacent second active structures 208, so that adjacent second active structures 208 are separated by the second field isolation layer pattern 226. The second field isolation layer pattern 226 may include an oxide such as silicon oxide.

Each of the first transistors includes a first gate structure, a first impurity region and a second impurity region 220. Here, the first gate structure has a first gate insulation layer pattern 206 and a first conductive layer pattern 216. Further, the first impurity region includes a first sub-region 212 and a second sub-region 214. The first sub-region 212 may have an impurity concentration relatively lower than that of the second sub-region 214.

The first gate insulation layer pattern 206 is located on a side of the upper portion 202 and on the lower portion 210 of the first active structure. An upper step of the lower portion 210 of the first active structure may be covered with the first gate insulation layer pattern 206. The first gate insulation layer pattern 206 may include silicon oxide or metal oxide.

The first conductive layer pattern 216 may enclose the upper portion 202 of the first active structure by interposing the first gate insulation layer pattern 206 therebetween. The first conductive layer pattern 216 may fill the gap between the first field isolation layer pattern 218 and the upper portion 202 of the first active structure. The first conductive layer pattern 216 may include doped polysilicon, metal and/or metal compound. The first conductive layer pattern 216 may have a height substantially smaller than the height of the upper portion 202 of the first active structure.

In some embodiments, the first conductive layer pattern 216 may have a first portion and a second portion prolonged from the first portion. The first portion of the first conductive layer pattern 216 may enclose the upper portion 302 of the first active structure, and the second portion of the first conductive layer pattern 216 may extend on the first field isolation layer pattern 218. The second portion of the first conductive layer pattern 216 may have a width substantially larger than a width of the first portion of the first conductive layer pattern 216.

An insulation interlayer 224 is formed on the first conductive layer pattern 216 between adjacent first active structures. The insulation interlayer 224 may include an oxide such as silicon oxide. A total height of the first conductive layer pattern 216 and the insulation interlayer 224 may be substantially the same as or substantially similar to the height of the upper portion 202 of the first active structure.

The first sub-region 212 of the first impurity region may be formed at the upper step of the lower portion 210 of the first active structure, and the second sub-region 214 of the first impurity region may be positioned at a lower step of the lower portion 210 of the first active structure. That is, the second sub-region 214 may locate beneath the first sub-region 212. The second sub-region 214 may make contact with the first sub-region 212. The second sub-region 214 of the first impurity region may serve as a bit line of a semiconductor device.

The second impurity region 220 is formed at the upper portion 206 of the first active structure. Thus, the second impurity region 220 may be separated from the first impurity region along a substantially vertical direction relative to the substrate 200.

The second transistors locate on the second active structures 208, respectively. Each of the second transistors includes a second gate structure (not illustrated) and third impurity regions 240. The second gate structure may have a construction substantially the same as that of the second gate structure described with reference to FIG. 4.

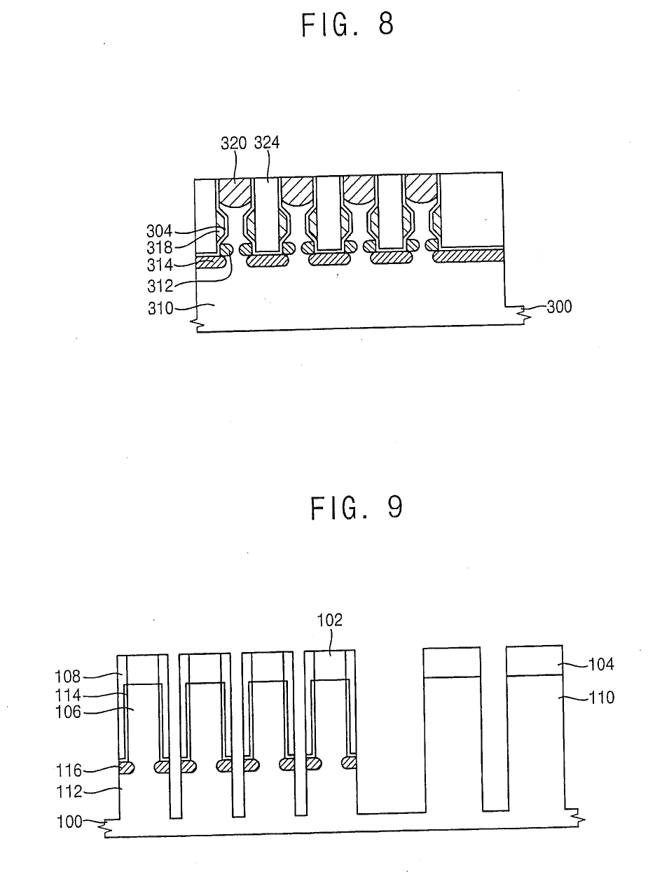

FIGS. 7 and 8 are cross-sectional views illustrating a semiconductor device in accordance with example embodiments.

Referring to FIGS. 7 and 8, the semiconductor device includes a substrate 300 having a first area and a second area, first active structures disposed in the first area, second active structures in the second area, first transistors in the first area, and second transistors in the second area.

Each of the first active structures includes an upper portion 302, a lower portion 310, and a recess formed on a central side of the upper portion 302. The lower portion 310 of the first active structure has a width substantially larger than a width of the upper portion 302. Since the recess is provided on the side of the upper portion 302 of the first active structure, the upper portion 302 of the first active structure may have a stepped side. Here, an upper side of the upper portion 302 of the first active structure may have a width substantially the same or substantially similar to a width of a lower side of the upper portion 302.

A first field isolation layer pattern 316 is disposed between adjacent first active structures. The field isolation layer pattern 316 may have a height substantially larger than a height of the lower portion 310 of the first active structure, whereas the height of the first field isolation layer pattern 316 may be substantially smaller that a height of the upper portion 302 of the first active structure. The first field isolation layer pattern 316 may include an oxide such as silicon oxide. An upper portion of the first field isolation layer pattern 316 may be protruded from the substrate 300 along a vertical direction. The upper portion of the first field isolation layer pattern 316 may have a substantially rectangular cross-section.

In example embodiments, a gap may be provided between the upper portion 302 of the first active structure and the upper portion of the first field isolation layer pattern 316, and further between the upper portion of the first field isolation layer pattern 316 and the lower portion 310 of the first active structure.

A second field isolation layer pattern 326 is disposed between adjacent second active structures 308. The second field isolation layer pattern 326 may include an oxide such as silicon oxide. The second field isolation layer pattern 326 may have a height substantially the same as or substantially similar to that of second active structure 308.

Each of the first transistors includes a first gate structure, a first impurity region and a second impurity region 320. The first gate structure includes a first gate insulation layer pattern 304 and a first conductive layer pattern 318. The first impurity region has a first sub-region 312 and a second sub-region 314.

The first gate insulation layer pattern 304 is disposed on a side of the upper portion 302 of the first active structure. The first gate insulation layer pattern 304 may be located along a profile of the upper portion 302 of the first active structure. The first gate insulation layer pattern 304 may include silicon oxide or metal oxide having a high dielectric constant. The first gate insulation layer pattern 304 may fill the gap between the upper portion of the first field isolation layer pattern 316 and the first active structure.

The first conductive layer pattern 318 is formed on the first gate insulation layer pattern 304. The first conductive layer pattern 318 may fill the recess of the upper portion 302 of the first active structure. The first conductive layer pattern 318 may have a first portion and a second portion. The first portion of the first conductive layer pattern 318 may enclose the upper portion 302 of the first active structure having the recess, and the second portion of the first conductive layer pattern 318 may extend from the first portion of the first conductive layer pattern 318. The first conductive layer pattern 318 may include doped polysilicon, metal and/or metal compound.

The first sub-region 312 of the first impurity region may be provided at a bottom of the upper portion 302 of the first active structure, and the second sub-region 314 of the first impurity region may be formed at an upper peripheral surface of the lower portion 310 of the first active structure. The first sub-region 312 of the first impurity region may be located under the recess of the upper portion 302 of the first active structure. The second sub-region 314 of the first impurity region may be positioned beneath the first sub-region 312 of the first impurity region to may make contact with the first sub-region 312. The second sub-region 314 of the first impurity region may have an impurity concentration substantially higher than that of the first sub-region 312.

The second impurity region 320 is formed at the upper portion 302 of the first active structure, so that the second impurity region 320 may be spaced apart from the first impurity region along a substantially vertical direction relative to the substrate 300.

Each of the second transistors includes a second gate structure (not illustrated) and third impurity regions 340. The second gate structure including a second gate insulation layer pattern and a second conductive layer pattern may have a construction substantially the same as or substantially similar to that of the second gate structure described with reference to FIG. 4.

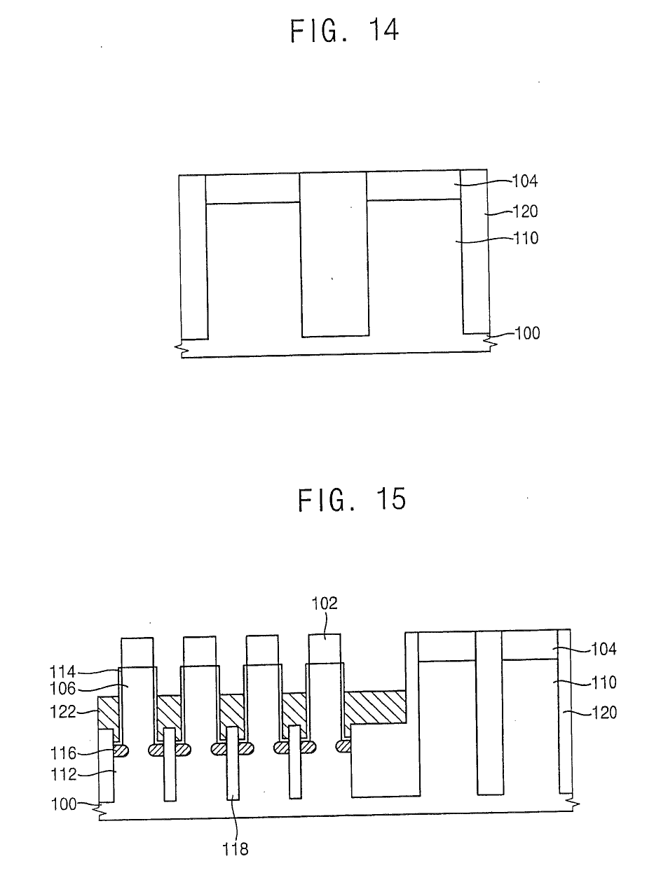

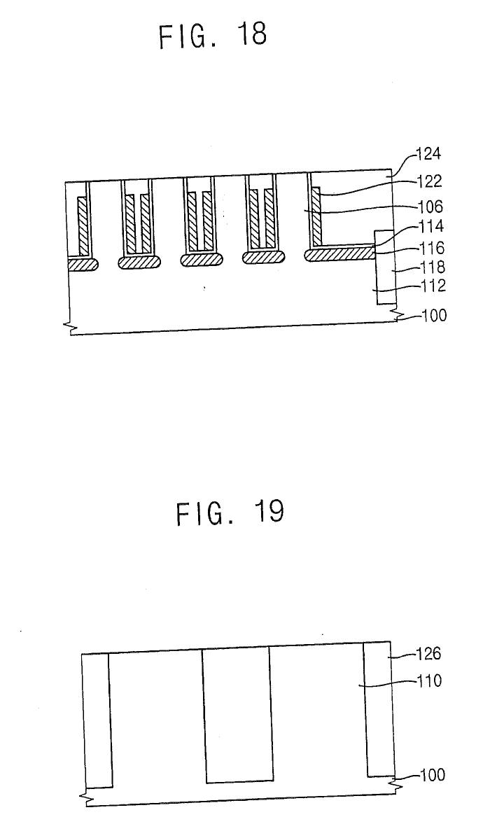

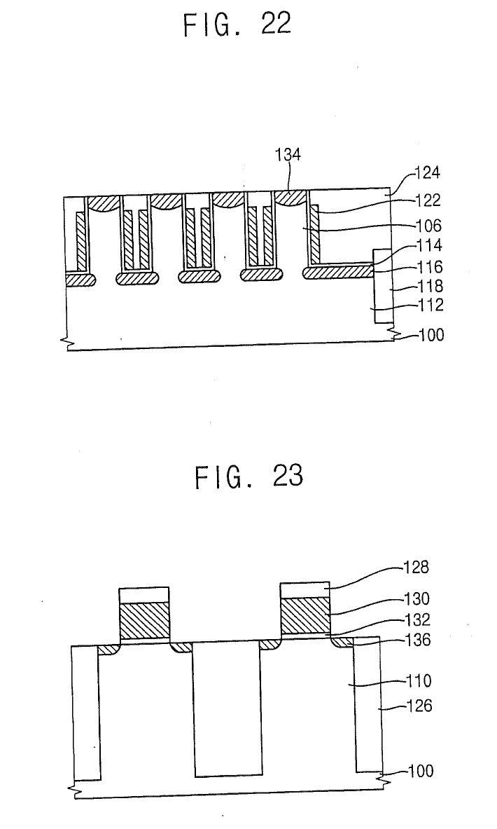

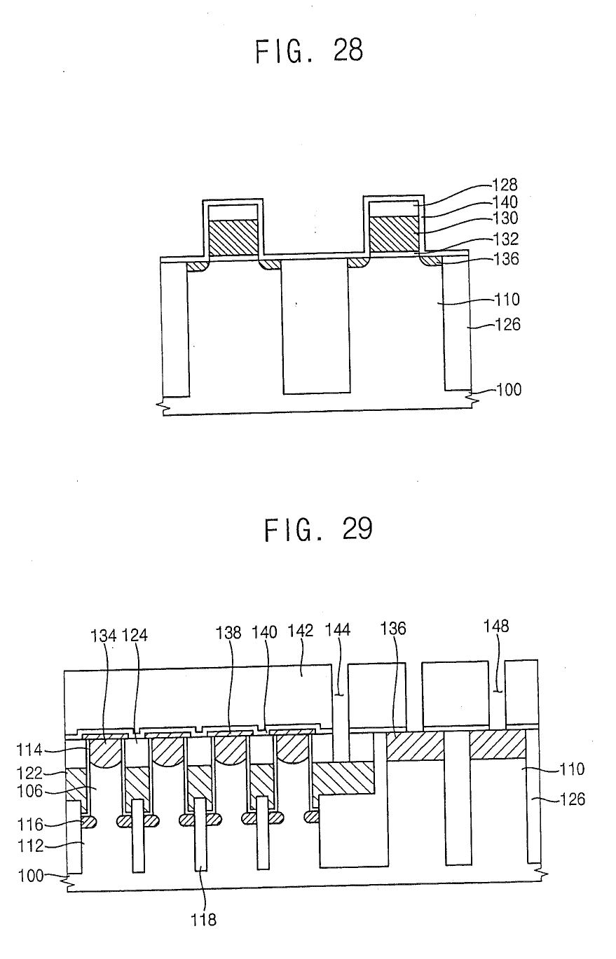

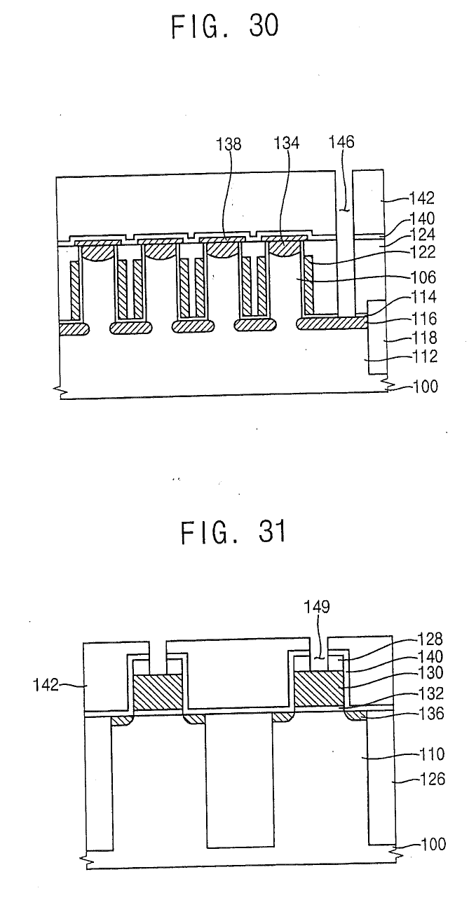

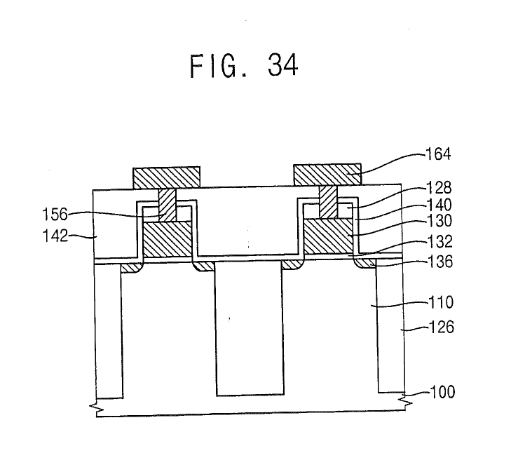

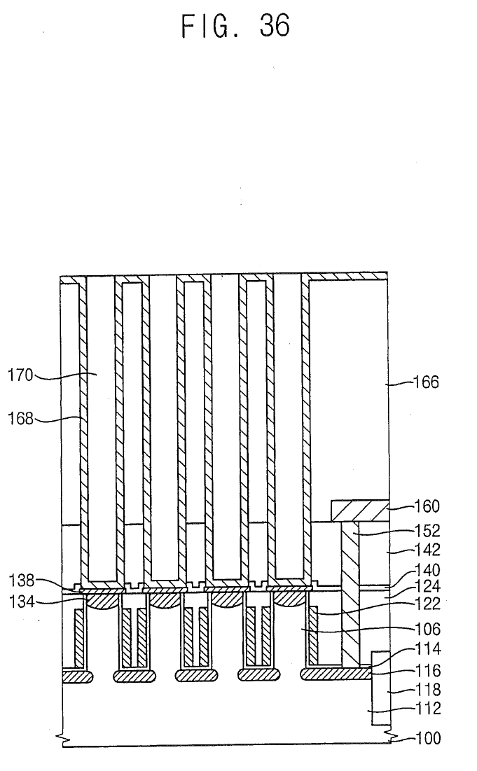

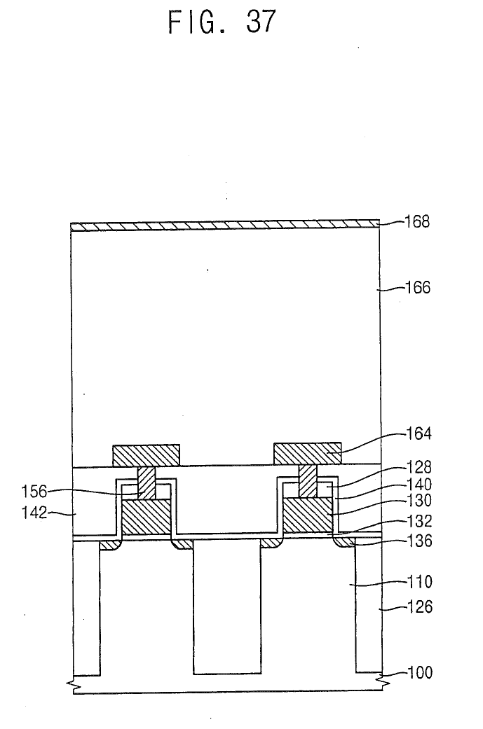

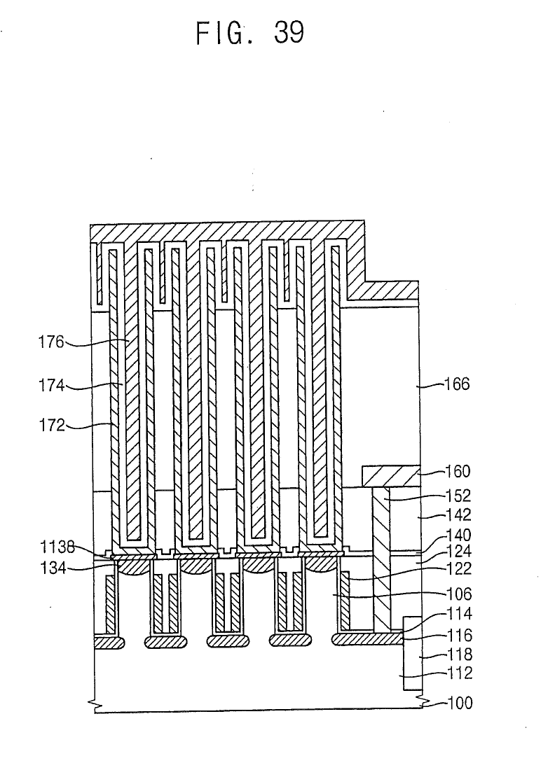

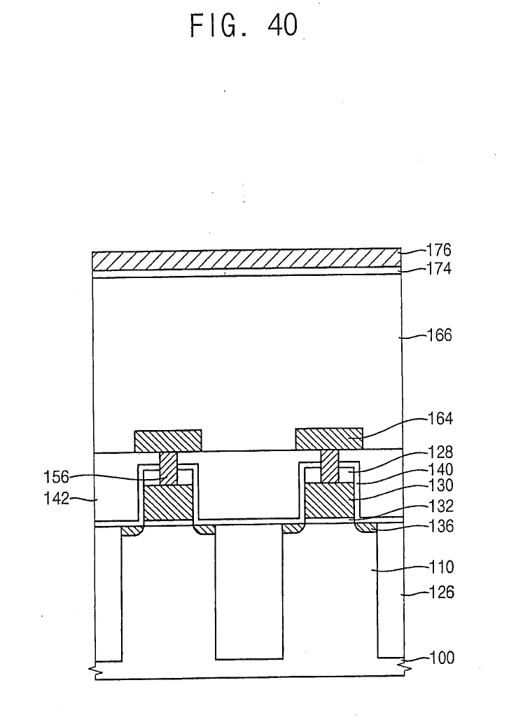

FIGS. 9 to 40 are cross-sectional views illustrating a method of manufacturing a semiconductor device in accordance with some embodiments.

Referring to FIGS. 9, 10 and 11, a first mask 102 and a second mask 104 are formed on a substrate 100 having a first area and a second area. The first area and the second area may correspond to a cell area and a peripheral area, respectively. Memory cells of the semiconductor device may be disposed in the first area and logic circuits of the semiconductor device may be formed in the second area. The substrate 100 may include a semiconductor substrate such as silicon substrate, germanium substrate, silicon germanium substrate, etc. Alternatively, the substrate 100 may include an SOI substrate or a GOI substrate.

The first mask 102 and the second mask 104 are positioned in the first area and the second area, respectively. Each of the first and the second masks 102 and 104 may be formed using a material that has an etching selectivity with respect to the substrate 100. For example, the first and the second masks 102 and 104 may be formed using silicon nitride or silicon oxynitride. The first and the second mask 102 and 104 may be formed by patterning an insulation layer after forming the insulation layer on the substrate 100.

In some embodiments, the first mask 102 may have a hexahedral structure, and the second mask 104 may have a bar shape or a line shape. The second mask 104 may extend in the second area along a first direction. The second mask 104 may have a second width substantially larger than a first width of the first mask 102.

In some embodiments, a pad oxide layer (not illustrated) may be formed on the substrate 100 before forming the first and the second masks 102 and 104 on the substrate 100. The pad oxide layer may reduce stresses generated between the substrate 100 and the first mask 102 and between the substrate 100 and the second mask 104. The pad oxide layer may be formed by a thermal oxidation process or a chemical vapor deposition (CVD) process. The pad oxide layer may include silicon oxide, germanium oxide, etc.

Using the first and the second masks 102 and 104 as etching masks, the substrate 100 is partially etched to form preliminary first active structures and preliminary second active structures. The preliminary first active structures are formed in the first area and the preliminary second active structures are positioned in the second area. The preliminary first active structures and the preliminary second active structures may be formed by an anisotropic etching process.

In some embodiments, each of the preliminary first active structures may have a height substantially the same as or substantially similar to a height of each preliminary second active structure. However, widths of the preliminary first active structures may be substantially smaller than those of the preliminary second active structures.

A first gate insulation layer (not illustrated) is formed on sidewalls of the preliminary first active structure and first portions of the substrate 100 exposed between adjacent preliminary first active structures. The first gate insulation layer may be formed in the first area only. Alternatively, the first gate insulation layer may be further formed in the first and the second areas of the substrate 100. The first gate insulation layer may be formed along profiles of the preliminary first active structures. The first gate insulation layer may be formed using an oxide or a metal oxide. For example, the first gate insulation layer may be formed using silicon oxide by a CVD process, a thermal oxidation process, an HDP-CVD process, etc. Alternatively, the first gate insulation layer may be formed using hafnium oxide, zirconium oxide, aluminum oxide or tantalum oxide by a CVD process, an atomic layer deposition (ALD) process, an evaporation process, a sputtering process, etc.

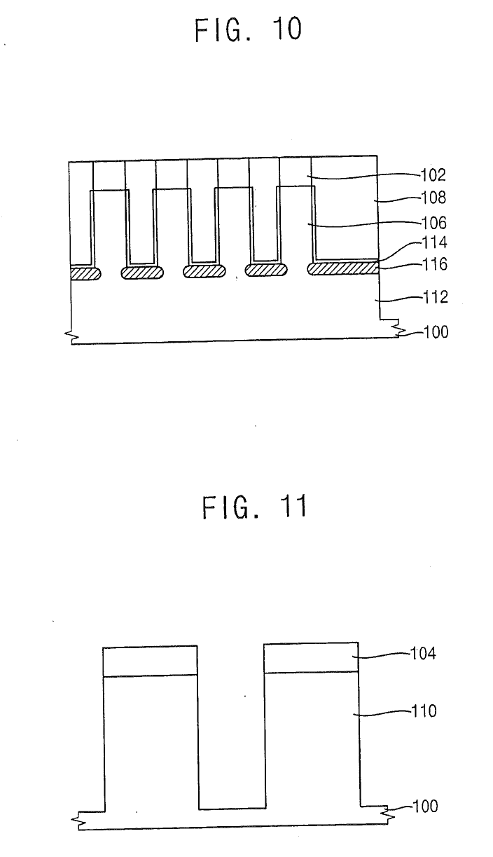

As illustrated in FIGS. 9 and 10, impurities are doped into the first portions of the substrate 100 between the preliminary first active structures using the first mask 102 as an implantation mask. Hence, preliminary impurity regions are formed at the first portions of the substrate 100. In some embodiments, a protection layer (not illustrated) may be formed to cover the preliminary second active structures while forming the preliminary first impurity regions in the first area. The protection layer may be formed using photoresist.

A third mask 108 is formed on the sidewalls of the preliminary first active structure and a sidewall of the first mask 102. The third mask 108 partially covers the first portions of the substrate 100, and thus portions of the first gate insulation layer on the first portions of the substrate 100 are exposed by the third mask 108. The third mask 108 may enclose upper portions of the preliminary first active structures and may extend along the first direction. The third mask 108 may be formed using an oxide, a nitride, an oxynitride, etc. For example, the third mask 108 may be formed using silicon oxide, silicon nitride, silicon oxynitride, etc.

The first portions of the substrate 100 and the first gate insulation layer are partially etched using the third mask 108 as an etching mask, so that first active structures, first gate insulation layer patterns 114 and first impurity regions 116 are formed in the first area of the substrate 100. Each of the first active structures includes an upper portion 106 and a lower portion 112 substantially wider than the upper portion 106. The first impurity region 116 is formed by partially etching the preliminary first impurity region. The first impurity region 116 is positioned at the lower portion 112 of the first active structure. For example, the first impurity region 116 may be located at an upper peripheral portion of the lower portion 112 of the first active structure. The first impurity region 116 may extend along the first direction. The first gate insulation layer pattern 114 may enclose the upper portion 106 of the first active structure. Further, the first gate insulation layer pattern 114 is formed on the first impurity region 116. That is, the first gate insulation layer pattern 114 may cover a sidewall of the upper portion 106 of the first active structure and the upper peripheral portion of the lower portion 112.

In some embodiments, the upper portion 106 of the first active structure may have a fin shape and the lower portion 112 of the first active structure may have a circular pillar shape or a polygonal pillar shape. The lower portion 112 of the first active structure may extend along the first direction. The lower portion 112 may have a width substantially larger than that of the upper portion 106.

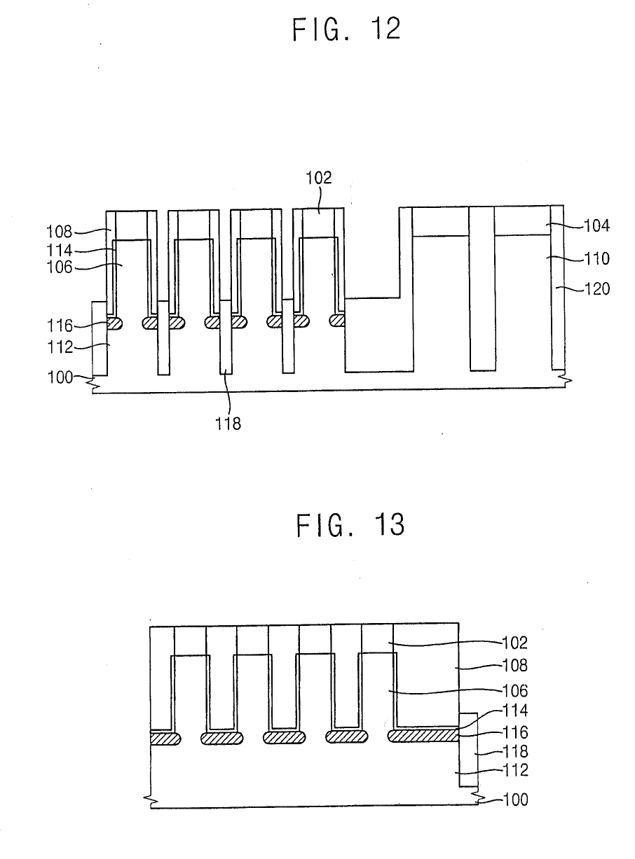

While forming the first active structures in the first area, second active structures 110 are formed in the second area by partially etching second portions of the substrate 100 between adjacent preliminary second active structures using the second mask 104 as an etching mask as illustrated in FIG. 11. Each of the second active structures 110 may have a height substantially the same as or substantially similar to a total height of the lower and the upper portions 112 and 106 of the first active structure. The lower portion 112 of the first active structure may have a width substantially similar to or substantially smaller than that of the second active structure 110.

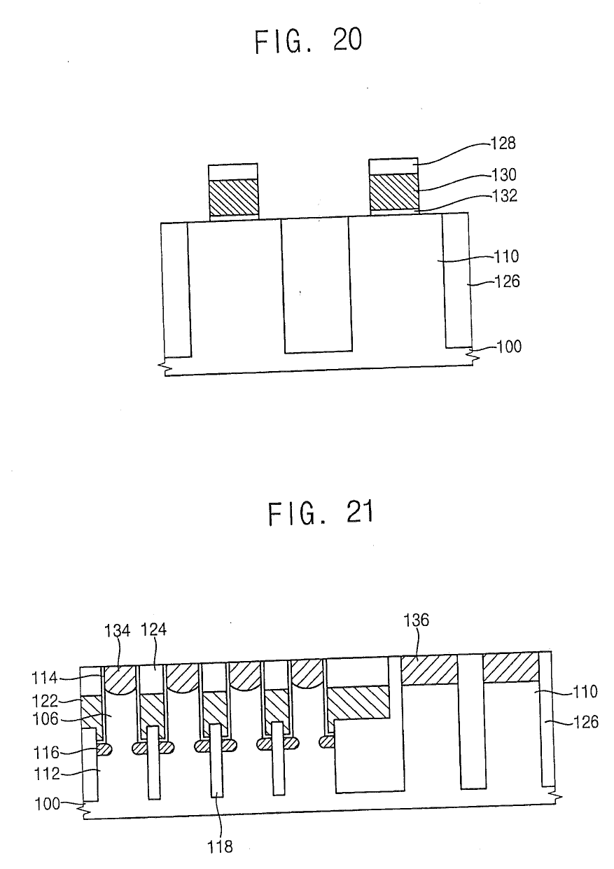

In some embodiments, adjacent second, active structures 110 may be completely separated from each other because the second active structures 110 have depths larger than that of the conventional active structures. Thus, adjacent third impurity regions 136 (see FIGS. 21 and 23) formed at upper portions of the second active structures 110 may be more electrically insulated from each other. That is, impurities in one of the third impurity regions 136 may not move into another of the third impurity regions 136 because adjacent third impurity regions 136 are completely insulated from each other.

Referring to FIGS. 12, 13 and 14, first field isolation layer patterns 118 are formed between the first active structures in the first area, and preliminary second field isolation layer patterns 120 are formed between second active structures 110 in the second area. Each of the first field isolation layer patterns 118 insulates adjacent first active structures from each other, and each of the preliminary second field isolation layer patterns 120 separates adjacent second structures 110 from each other.

In some embodiments, a field isolation layer (not illustrated) is formed on the substrate 100 to cover the first active structures and the second structures 110. The field isolation layer may be formed using an oxide such as silicon oxide by a CVD process, a PECVD process, a spin coating process, an HDP-CVD process, etc. For example, the field isolation layer may be formed using USG, SOG, FOX, FSG, TOSZ, BPSG, PSG, TEOS, PE-TEOS, HDP-CVD oxide, etc. The field isolation layer may be partially removed until upper faces of the first active structures and the second active structures 110 are exposed. Thus, preliminary first field isolation layer patterns (not illustrated) may be formed between the first active structures in the first area, and the preliminary second field isolation layer patterns 120 may be formed between the second active structures 110 in the second area. The preliminary first field isolation layer patterns and the preliminary second field isolation layer patterns 120 may be formed by a chemical mechanical polishing (CMP) process and/or an etch-back process. The preliminary first field isolation layer patterns may be partially etched to thereby form the first field isolation layer patterns 118 between the first active structures. Here, a protection layer (not illustrated) may be provided in the second area to cover the second active structures 110 and the preliminary second field isolation layer patterns 120. The protection layer may be formed using a material that may be easily removed from the second area. For example, the protection layer may be formed using photoresist.

In some embodiments, each of the first field isolation layer patterns 118 may have a height substantially larger than the height of the lower portion 112 of the first active structure. However, the height of the first field isolation layer patterns may be substantially smaller than the height of the upper portion 106 of the first active structure. Namely, an upper face of the first field isolation layer pattern 118 may be positioned between an upper face of the lower portion 112 and an upper face of the upper portion 106.

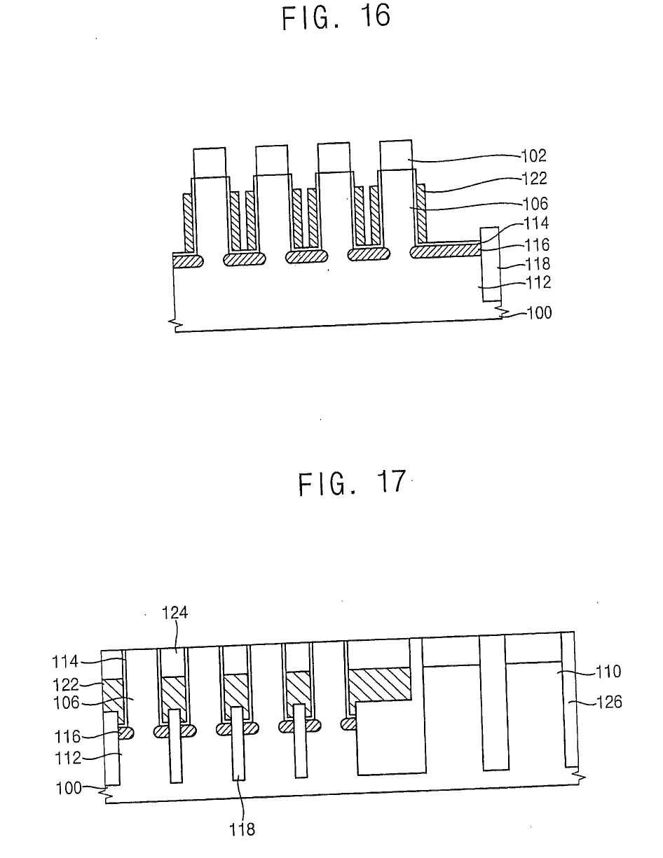

Referring to FIGS. 15 and 16, the third mask 108 is removed from the first area to expose the first gate insulation layer pattern 114 on the sidewall of the upper portion 106 of the first active structure. When the third mask 108 is removed from the first gate insulation layer pattern 114, a gap may be provided between the upper portion of the first field isolation layer pattern 118 and the upper portion 106 of the first active structure. That is, the upper portion of the first field isolation layer pattern 118 may be protruded from the first gate insulation layer pattern 114 along a substantially upward direction relative to the substrate 100.

A first conductive layer (not illustrated) is formed in the first area to cover the first mask 102 and the first gate insulation layer pattern 114. The first conductive layer may sufficiently fill up the gap between the first field isolation layer pattern 118 and the first active structure. The first conductive layer may be formed using polysilicon, a metal and/or a metal nitride. For example, the first conductive layer may be formed using polysilicon doped with impurities, tungsten, titanium, aluminum, tantalum, aluminum nitride, titanium nitride, tungsten nitride, tantalum nitride, etc. Further, the first conductive layer may be formed by a CVD process, a PECVD process, an ALD process, a sputtering process, an evaporation process, etc.

In some embodiments, the first conductive layer may be planarized until the first mask 102 is exposed. The first conductive layer may be planarized by a CMP process and/or an etch-back process.

The first conductive layer is partially removed after providing a fourth mask (not illustrated) on the first mask 102. The fourth mask may extend along a second direction substantially perpendicular to the first direction. The fourth mask may be formed using a nitride or an oxynitride. For example, the fourth mask may be formed using silicon nitride or silicon oxynitride.

Using the fourth mask as an etching mask, the first conductive layer is etched to form first conductive layer patterns 122 on the first field isolation layer patterns 118. Each of the first conductive layer patterns 122 may be prolonged along the second direction such as the fourth mask.

In some embodiments, the first conductive layer pattern 122 includes a first portion and a second portion. The first portion of the first conductive layer pattern 122 may enclose the upper portion 106 of the first active structure. The second portion of the first conductive layer pattern 122 may extend from the first portion of the first conductive layer pattern 122 along the second direction. Since the first portion of the first conductive layer pattern 122 fills the gap between the upper portion of the first field isolation layer pattern 118 and the upper portion 106 of the first active structure, the first portion of the first conductive layer pattern 122 may protrude toward the substrate 100 rather than the second portion of the first conductive layer pattern 122. The first portion of the first conductive layer pattern 122 may serve as a gate electrode of a first transistor, and the second portion of the first conductive layer pattern 122 may function as a word line of a semiconductor device.

In some embodiments, an upper portion of the first conductive layer pattern 122 may be etched, so that the first conductive layer pattern 122 may have a height lower than the height of the upper portion 106 of the first active structure.

While forming the first conductive layer pattern 122 in the first area, a protection layer (not illustrated) may be formed in the second area to cover the second active structure 110 and the preliminary second field isolation layer pattern 120. The protection layer may be formed using photoresist.

Referring to FIGS. 17, 18 and 19, a first insulation interlayer (not illustrated) is formed in the first area to cover the first conductive layer patterns 122 and the first mask 102. The first insulation interlayer may be formed using an oxide such as silicon oxide. For example, the first insulation interlayer may be formed using BPSG, PSG, TEOS, PE-TEOS, USG, SOG, FOX, FSG, TOSZ, HDP-CVD oxide, etc. Further, the first insulation interlayer may be formed by a CVD process, a PECVD process, a spin coating process, an HDP-CVD process, etc. In example embodiments, the first insulation interlayer may include an oxide substantially the same as or substantially similar to that of the field isolation layer. Alternatively, the first insulation interlayer and the field isolation layer may be formed using different oxides, respectively.

In some embodiments, the first insulation interlayer may be planarized until the first mask 102 is exposed, so that the first insulation interlayer may have a level upper face. Here, the first insulation interlayer may be planarized by a CMP process and/or an etch-back process.

The first and the second masks 102 and 104 are removed from the first active structure and the second active structure 110, so that the upper portion 106 of the first active structure and the upper portion of the second active structure 110 are exposed. In some embodiments, upper portions of the first insulation interlayer and the preliminary second field isolation layer pattern 120 may be partially etched while removing the first and the second masks 102 and 104, thereby forming a first insulation interlayer pattern 124 and a second field isolation layer pattern 126. The first insulation interlayer pattern 124 may be disposed in the first area and the second field isolation layer pattern 126 may be formed in the second area.

In some embodiments, a preliminary second impurity region (not illustrated) may be formed at an upper side of the upper portion 106 of the first active structure. Namely, impurities may be implanted into the upper side of the upper portion 106 of the first active structure by a predetermined angle relative to the first active structure.

Referring to FIG. 20, a second gate insulation layer (not illustrated) and a second conductive layer (not illustrated) are successively formed on the second active structure 110 and the second field isolation layer pattern 126. The second gate insulation layer may be formed using silicon oxide or a metal oxide by a thermal oxidation process, a CVD process an ALD process, a sputtering process, etc. Examples of the metal oxide in the second gate insulation layer may include hafnium oxide, aluminum oxide, tantalum oxide, zirconium oxide, etc. The second conductive layer may be formed using polysilicon, a metal and/or a metal compound by a CVD process, a PECVD process, a sputtering process, an ALD process, an evaporation process, etc. For example, the second conductive layer may be formed using polysilicon doped with impurities, titanium, titanium nitride, tungsten, tungsten nitride, etc. Further, the second conductive layer may have a single layer structure or a multi layer structure.

A gate mask 128 is formed on the second conductive layer. The gate mask 128 may be formed using a material that has an etching selectivity relative to the second active structure 110, the second field isolation layer pattern 126, the second gate insulation layer and the second conductive layer. For example, the gate mask 128 may be formed using silicon nitride or silicon oxynitride. The gate mask 128 may have a bar shape or a line shape extending along the second direction.

The second conductive layer and the second gate insulation layer are etched using the gate mask 128 as an etching mask, such that a second gate insulation layer pattern 132 and a second conductive layer pattern 130 are formed on the second active structure 110. The second gate insulation layer pattern 132 may electrically insulate the second conductive layer pattern 130 from the second active structure 110. The second conductive layer pattern 130 may serve as a gate electrode of a second transistor.

Referring to FIGS. 21, 22 and 23, a second impurity region 134 is formed at the upper portion 106 of the first active structure, and the third impurity regions 136 are formed at the upper portion of the second active structure 110. The second and the third impurity regions 134 and 136 may be simultaneously formed. The second impurity region 134 may be formed at a whole surface of the upper portion 106 of the first active structure. The third impurity regions 136 may be positioned portions of the second active structure 110 adjacent to the second conductive layer pattern 130.

In some embodiments, the second impurity region 134 may include a first sub-region and a second sub-region. The first sub-region of the second impurity region 134 may be positioned at the upper side of the upper portion 106 of the first active structure, and the second sub-region of the second impurity region 134 may be formed at a surface of the upper portion 106 of the first active structure. Here, the second sub-region of the second impurity region 134 may have an impurity concentration substantially higher than that of the first sub-region of the second impurity region 134.

In some embodiments, each of the third impurity regions 136 may also include a first sub-region having a relatively low impurity concentration and a second sub-region having a relatively high impurity concentration. The first sub-region of the third impurity region 136 may be formed at the upper portion of the second active structure 110, and the second sub-region of the third impurity region 136 may be adjacent to the first sub-region of the third impurity region 136. After forming the first sub-region of the third impurity region 136, a gate spacer may be formed on sidewalls of the second gate insulation layer pattern 132, the second conductive layer pattern 130 and the gate mask 128. Then, the second sub-region of the third impurity region 136 may be provided. The gate spacer may be formed using silicon nitride or silicon oxynitride.

Through the above-described processes, a first transistor and a second transistor are formed in the first area and the second area, respectively. The first transistor includes a first gate structure, the first impurity region 116 and the second impurity region 134. The first gate structure has the first gate insulation layer pattern 114 and the first conductive layer pattern 122. The second transistor includes a second gate structure, the gate mask 128 and the third impurity regions 136. The second gate structure includes the second gate insulation layer pattern 132 and the second conductive layer pattern 130.

In some embodiments, a channel region of the first transistor may be provided in the upper portion 106 of the first active structure because the first impurity region 116 is formed at the lower portion 112 of the first active structure and the second impurity region 134 is disposed at the upper portion 106 of the first active structure. That is, the channel region of the first transistor may be generated along a direction substantially perpendicular to the substrate 100. Thus, the first transistor may be referred to as a vertical channel transistor.

A channel region of the second transistor may occur at the upper portion of the second active structure 110 between the third impurity regions 136. The channel region of the second transistor may be formed at the upper portion of the second active structure 110 along a direction substantially in parallel to the substrate 100. Hence, the second transistor may be referred to as a horizontal channel transistor.

According to some embodiments, a contact, a plug, a pad, a conductive pattern, a wiring and/or a capacitor may be easily formed in the first and the second areas of the substrate 100 because the first active structure may have a height substantially the same as or substantially similar to the height of the second active structure 110. That is, the contact, the plug, the pad, the conductive pattern, the wiring and/or the capacitor may be formed without any failure since a height difference or a step may not be generated between the first active structure and the second active structure 110.

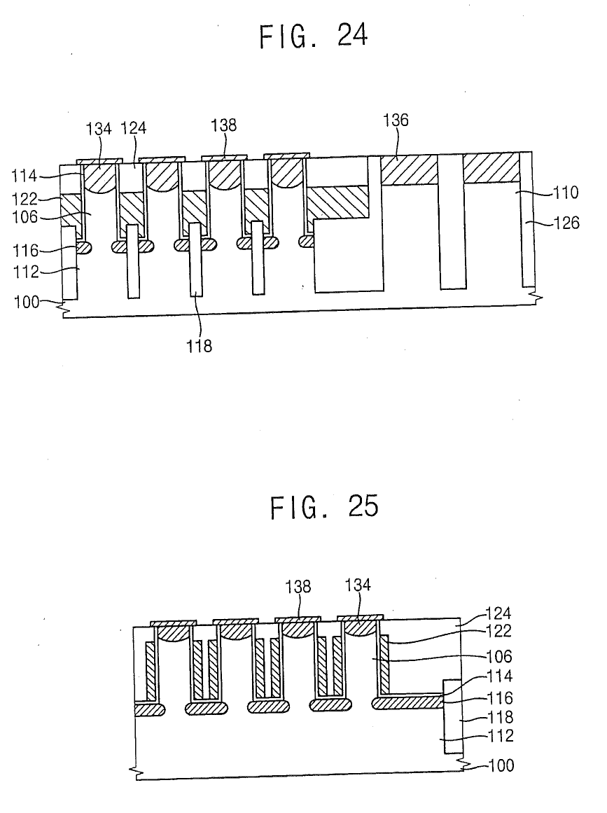

Referring to FIGS. 24 and 25, an epitaxial silicon pattern 138 are formed on the second impurity region 134 of the first transistor. The epitaxial silicon pattern 138 may be formed by a selective epitaxial growth (SEG) process. In the SEG process, the epitaxial silicon pattern 138 may not be formed on the first insulation interlayer pattern 124 when the first insulation interlayer layer pattern 124 includes oxide. However, the epitaxial silicon pattern 138 may be grown on the upper portion 106 of the first active structure when the first active structure includes silicon.

In some embodiments, the epitaxial silicon pattern 138 may have a width substantially larger than a width of the second impurity region 134 because the epitaxial silicon pattern 138 may be grown along a vertical direction as well as a horizontal direction. When the epitaxial silicon pattern 138 is provided between the second impurity region 134 and the contact, the plug or the pad, a contact resistance between the second impurity region 134 and the contact, the pad or the plug may be reduced.

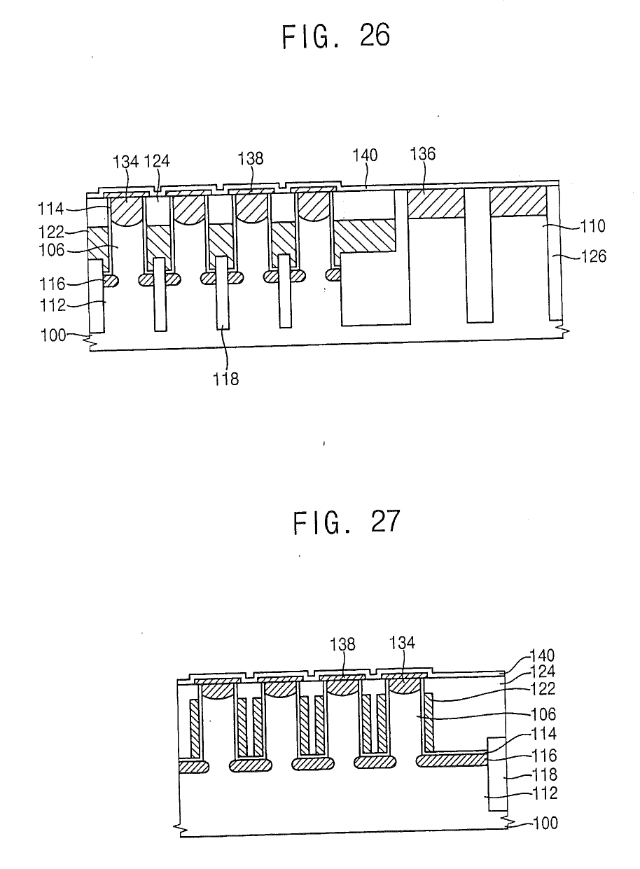

Referring to FIGS. 26, 27 and 28, an etch stop layer 140 is formed on the epitaxial silicon pattern 138, the first insulation interlayer pattern 124, the second active structure 110, the second field isolation layer pattern 126 and the gate mask 128. That is, the etch stop layer 140 is formed in the first and the second areas of the substrate 100. The etch stop layer 140 may be continuously formed along profiles of the epitaxial silicon pattern 138, the first insulation interlayer pattern 124, the second active structure 110, the second field isolation layer pattern 126 and the second transistor.

In some embodiments, the etch stop layer 140 may be formed using a material that has an etching selectivity with respect to oxide. For example, the etch stop layer 140 may be formed using a nitride such as silicon nitride.

Referring to FIGS. 29, 30 and 31, a second insulation interlayer 142 is formed on the etch stop layer 140. Thus, the second insulation interlayer 142 is positioned in the first and the second areas of the substrate 100. The second insulation interlayer 142 may have a thickness that sufficiently covers the second transistor.

In some embodiments, the second insulation interlayer 142 may be formed using an oxide by a CVDD process, a PECVD process, a spin coating process, an HDP-CVD process, etc. For example, the second insulation interlayer 142 may be formed using BPSG, PSG, TEOS, PE-TEOS, USG, SOG, FOX, FGS, TOSZ, HDP-CVD oxide, etc. The second insulation interlayer 142 may include an oxide substantially the same as or substantially similar to that of the first insulation interlayer pattern 124. Alternatively, the second insulation interlayer 142 may be formed using an oxide different from that of the first insulation interlayer pattern 124.

In some embodiments, an upper portion of the second insulation interlayer 142 may be planarized by a planarization process, for example, a CMP process and/or an etch-back process. Thus, the second insulation interlayer 142 may have a flat upper face.

A fifth mask (not illustrated) is provided on the second insulation interlayer 142, and then the second insulation interlayer 142, the etch stop layer 140, the first insulation interlayer pattern 124 and the gate mask 128 are partially etched using the fifth mask as an etching mask. Hence, a first contact hole 144, a second contact hole 146, a third contact hole 148 and a fourth contact hole 149 are formed through the second insulation interlayer 142, the etch stop layer 140, the first insulation interlayer pattern 124 and/or the gate mask 128. The fifth mask may be formed using a nitride such as silicon nitride or an oxynitride such as silicon oxynitride.

The first and second contact holes 144 and 146 are formed through the second insulation interlayer 142, the etch stop layer 142 and the first insulation interlayer pattern 124 in the first area of the substrate 100. The first contact hole 144 exposes a second portion of the first conductive layer pattern 122, and the second contact hole 146 exposes the first impurity region 116.

The third and the fourth contact holes 148 and 149 are provided in the second area of the substrate 100. The third contact hole 148 is formed through the second insulation interlayer 142 and the etch stop layer 140, so that the third impurity regions 136 are exposed by the third contact hole 148. The fourth contact hole 149 is formed through the second insulation interlayer 142, the etch stop layer 140 and the gate mask 128, such that the second conductive layer pattern 130 is exposed by the fourth contact hole 149.

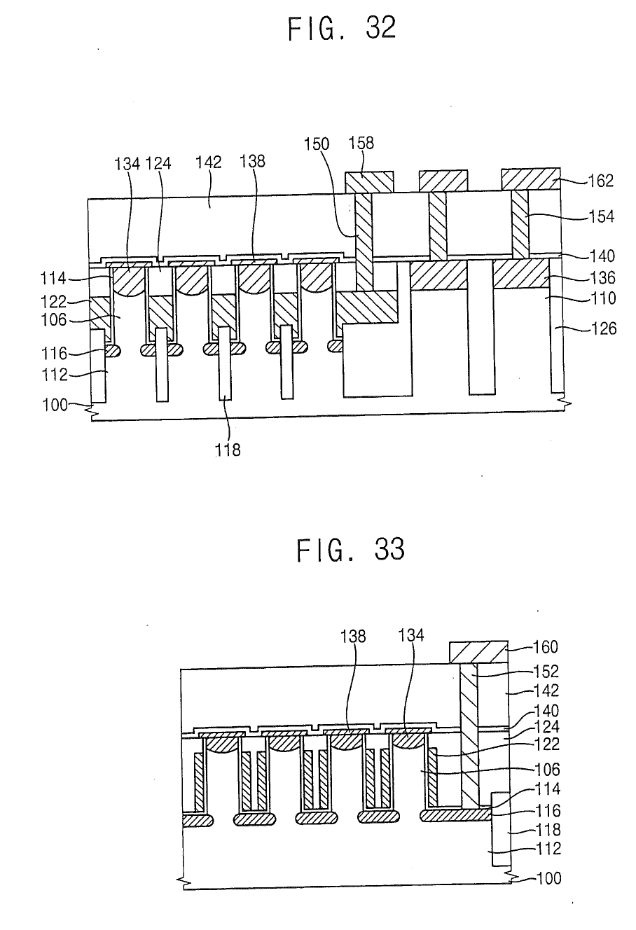

Referring to FIGS. 32, 33 and 34, a third conductive layer (not illustrated) is formed on the second insulation interlayer 142 to fill the first to the fourth contact holes 144, 146, 148 and 149. The third conductive layer may be formed using a metal, a metal compound and/or polysilicon. For example, the third conductive layer may be formed using tungsten, titanium, aluminum, copper, tantalum, tungsten nitride, aluminum nitride, titanium nitride, doped polysilicon, etc. Further, the third conductive layer may be formed by a CVD process, an ALD process, a PECVD process, a sputtering process, an evaporation process, etc.

The third conductive layer is partially removed until the second insulation interlayer 142 is exposed, thereby forming a first contact 150, a second contact 152, a third contact 154 and a fourth contact 156. The first to the fourth contacts 150, 152, 154 and 156 are formed in the first to the fourth contact holes 144, 146, 148 and 149, respectively. The first and the second contacts 150 and 152 may be electrically connected to the first transistor. The third and the fourth contacts 154 and 156 may make electrically contact with the second transistor.

The first and the second contacts 150 and 152 are disposed in the first area of the substrate 100. The first contact 150 filling the first contact hole 144 makes electrical contact with the first conductive layer pattern 116, and the second contact 152 filling the second contact hole 146 makes electrical contact with the first impurity region 116.

The third and the fourth contacts 154 and 156 are positioned in the second area of the substrate 100. The third contact 154 filling the first contact hole 148 is electrically connected to the third impurity regions 136, and the fourth contact 156 filling the fourth contact hole 149 is electrically connected to the second conductive layer pattern 130.

A fourth conductive layer (not illustrated) is formed on the second insulation layer 142, the first contact 150, the second contact 152, the third contact 154 and the fourth contact 156. The fourth conductive layer may be formed using a metal, a metal compound and/or polysilicon. For example, the fourth conductive layer may be formed using tungsten, titanium, aluminum, copper, tantalum, tungsten nitride, aluminum nitride, titanium nitride, doped polysilicon, etc. The fourth conductive layer may be formed by a CVD process, an ALD process, a PECVD process, a sputtering process, an evaporation process, etc.

The fourth conductive layer is patterned to provide a first wiring 158, a second wiring 160, a third wiring 162 and a fourth wiring 164 on the second insulation interlayer 142. The first to the fourth wirings 158, 160, 162 and 164 are formed on the first to the fourth contacts 150, 152, 154 and 156, respectively. Thus, the first to the fourth wirings 158, 160, 162 and 164 make electrical contact with the first to the fourth contacts 150, 152, 154 and 156, respectively.

In some embodiments, a third insulation interlayer (not illustrated) may be formed on the second insulation interlayer 142. The third insulation interlayer may be formed using an oxide such as silicon oxide by a CVD process, a PECVD process, a spin coating process, an HDP-CVD process, etc. For example, the third insulation interlayer may be formed using BPSG, PSG, SOG, USG, FOX, FSG, TOSZ, TEOS, PE-TEOS, HDP-CVD oxide, etc. The third insulation interlayer may be partially etched to form openings that expose the first to the fourth contacts 150, 152, 154 and 156. Then, the fourth conductive layer may be provided on the third insulation interlayer to thereby form the first to the fourth wirings 158, 160, 162 and 164.

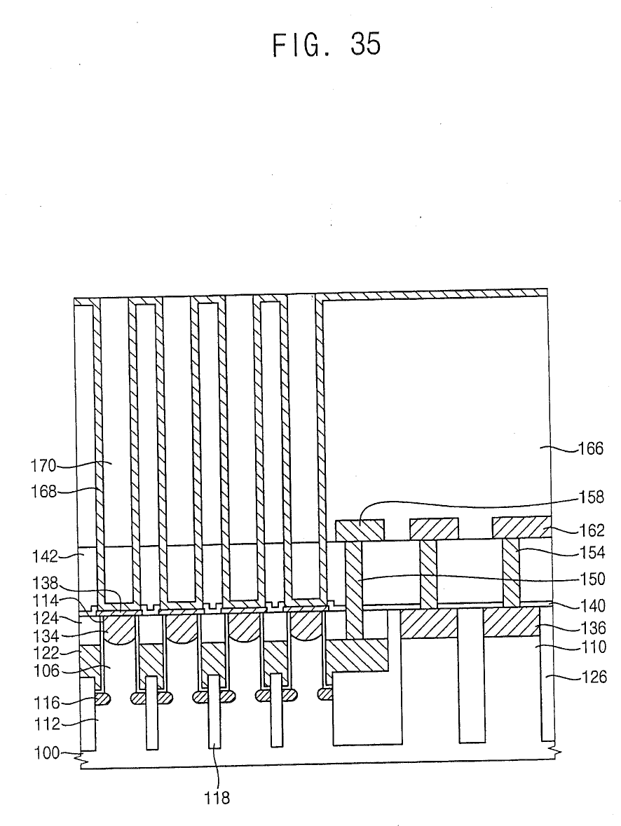

Referring to FIGS. 35, 36 and 37, a third insulation interlayer 166 is formed on the second insulation interlayer 142, the first wiring 158, the second wiring 160, the third wring 162 and the fourth wiring 164. The third insulation interlayer 166 may be formed using an oxide such as silicon oxide by a CVD process, a PECVD process, a spin coating process, an HDP-CVD process, etc. For example, the third insulation interlayer 166 may be formed using BPSG, PSG, USG, SOG, FOX, FSG, TOSZ, TEOS, PE-TEOS, HDP-CVDD oxide, etc. The third insulation interlayer 166 may include an oxide substantially the same as or substantially similar to that of the second insulation interlayer 142 and/or the first insulation interlayer pattern 124. Alternatively, the third insulation interlayer 166 may include an oxide different from that of the second insulation interlayer 142 and/or the first insulation interlayer pattern 124.

After a sixth mask (not illustrated) is provided on the third insulation interlayer 166, the third insulation interlayer 166, the second insulation interlayer 142 and the etch stop layer 140 are partially etched. Hence, an opening (not illustrated) exposing the epitaxial silicon pattern 138 is formed through the third insulation interlayer 166 to the etch stop layer 140. The opening may be formed by an anisotropic etching process.

A fifth conductive layer 168 is formed on the exposed epitaxial silicon pattern 138, a sidewall of the opening and the third insulation interlayer 166. The fifth conductive layer 168 may be continuously formed along a profile of the opening, so that the fifth conductive layer 168 may not fill up the opening. The fifth conductive layer 168 may be formed using polysilicon, a metal and/or a metal compound. For example, the fifth conductive layer 168 may be formed using doped polysilicon, tungsten, tungsten nitride, aluminum, aluminum nitride, titanium, titanium nitride, titanium aluminum nitride, tantalum, tantalum nitride, etc. Further, the fifth conductive layer 168 may be formed by a sputtering process, a CVD process, an ALD process, an evaporation process, etc.

A sacrificial layer 170 is formed on the fifth conductive layer 168 to fill the opening. The sacrificial layer 170 may be formed using an oxide, for example, USG, SOG, FOX, FSG, TOSZ, TEOS, PE-TEOS, FSG, TOSZ, BPSG, PSG etc. The sacrificial layer 170 may be formed by a CVD process, a PECVD process, a spin coating process, etc. The sacrificial layer 170 may include an oxide substantially the same or substantially similar to that of the third insulation interlayer 168, the second insulation interlayer 142 and/or the first insulation interlayer pattern 124. Alternatively, the sacrificial layer 170 may include an oxide different from that of the third insulation interlayer 168, the second insulation interlayer 142 and/or the first insulation interlayer pattern 124.

In some embodiments, an upper portion of the sacrificial layer 170 may be planarized until the fifth conductive layer 168 is exposed. The sacrificial layer 170 may be planarized by a CMP process and/or an etch-back process.

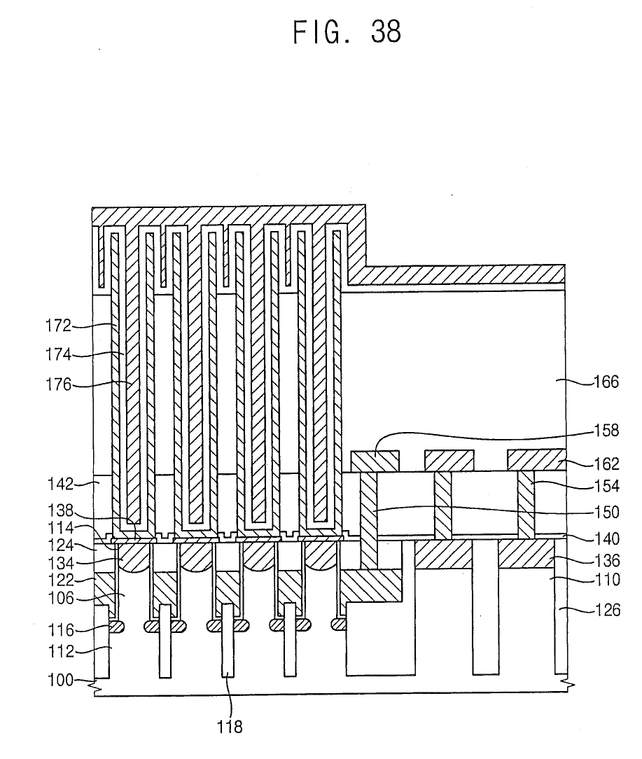

Referring to FIGS. 38, 39 and 40, the fifth conductive layer 168 is partially removed to provide a lower electrode 172 in the opening. The lower electrode 172 is formed on the exposed epitaxial silicon pattern 138 and the sidewall of the opening.

The sacrificial layer 170 is removed from the lower electrode 172. The sacrificial layer 170 may be etched using an etching solution or an etching gas including hydrogen fluoric acid. When the sacrificial layer 170 is removed, an upper portion of the third insulation interlayer 166 may be etched because the sacrificial layer 170 and the third insulation interlayer 166 include oxides, respectively. Thus, the lower electrode 172 may protrude from the third insulation interlayer 166.

A dielectric layer 174 is formed on the lower electrode and the third insulation interlayer 166. The dielectric layer 174 may be conformally formed along a profile of the lower electrode 172. The dielectric layer 174 may be formed using an oxide and/or a nitride. For example, the dielectric layer 174 may have an oxide/nitride/oxide (ONO) structure that includes a lower oxide film, a nitride film and an upper oxide film. Alternatively, the dielectric layer 174 may be formed using a metal oxide having a high dielectric constant. Examples of the metal oxide in the dielectric layer 174 may include yttrium oxide (YOx), hafnium oxide, zirconium oxide, aluminum oxide, tantalum oxide, niobium oxide (NbOx), etc.

An upper electrode 176 is formed on the dielectric layer 174. The upper electrode 176 may be formed using polysilicon, a metal and/or a metal compound. For example, the upper electrode 176 may be formed using polysilicon doped with impurities, titanium, aluminum, tantalum, copper, tungsten, titanium nitride, aluminum nitride, tungsten nitride, tantalum nitride, etc. Further, the upper electrode 176 may be formed by a sputtering process, a CVD process, an ALD process, an evaporation process, etc.

When the upper electrode 176 is provided on the dielectric layer 174, a capacitor including the lower electrode 172, the dielectric layer 174 and the upper electrode 176 is formed in the first area of the substrate 100. The capacitor is positioned on the epitaxial silicon pattern 138, so that the capacitor is electrically connected to the second impurity region 134 of the first transistor. Since the epitaxial silicon pattern 138 has the area substantially larger than that of the second impurity region 134, a contact resistance between the capacitor and the second impurity region may be reduced, whereas an electrical connection between the capacitor and the first transistor may be improved.

According to some embodiments, a first active structure on which a vertical channel transistor is formed may have a height substantially the same or substantially similar to a height of a second active structure where a horizontal channel transistor is provided. Thus, upper structures such as a pad, a contact, a wiring and/or a capacitor may be easily formed on the first and the second active structures without any step or any failure of the pad, the contact, the wiring and/or the capacitor. Additionally, an epitaxial silicon pattern may be provided between the vertical channel transistor and one of the upper structures, so that a contact resistance between the vertical channel transistor and the upper structure may be reduced and an electrical connection between the vertical channel transistor and the upper structure may be enhanced.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

1.-12. (canceled)

13. A method of manufacturing a semiconductor device, comprising:
forming a first active structure and a second active structure by partially etching a substrate having a first area and a second area, wherein the first active structure has a height substantially the same as a height of the second active structure;
forming a first transistor in the first area, wherein the first transistor includes a first gate structure enclosing an upper portion of the first active structure, a first impurity region formed at a lower portion of the first active structure, and a second impurity region formed at the upper portion of the first active structure; and
forming a second transistor in the second area, wherein the second transistor includes a second gate structure formed on the second active structure and third impurity regions formed at an upper portion of the second active structure.

14. The method of claim 13, further comprising forming an epitaxial silicon pattern on the second impurity region by a selective epitaxial growth process.

15. The method of claim 14, further comprising forming a capacitor in the first area, wherein the capacitor has a lower electrode making contact with the epitaxial silicon pattern.

16. The method of claim 13, wherein forming the first active structure and forming the second active structure comprise:
forming a first mask in the first area and a second mask in the second area, the first mask having a rectangular structure and the second mask having a bar or a line structure extending along a first direction;
partially etching the substrate using the first and the second mask as etching masks, to form a preliminary first active structure and a preliminary second active structure;
forming a third mask enclosing the preliminary first active structure and extending along the first direction; and
partially etching the substrate using the second and the third masks as etching masks, to form the first active structure and the second active structure.

17. The method of claim 16, further comprising forming a preliminary first impurity region at a portion of the substrate between adjacent first active structures before forming the third mask.

18. The method of claim 17, wherein forming the first transistor comprises:
forming a first gate insulation layer on the preliminary first impurity region and a side of the upper portion of the first active structure;
forming a first conductive layer on the first gate insulation layer to cover the first active structure; and
partially etching the first conductive layer, the first gate insulation layer and the preliminary first impurity region.

19. The method of claim 13, further comprising:
forming an isolation layer on the substrate to cover the first active structure and the second active structure; and
partially removing the field isolation layer to form a first field isolation layer pattern in the first area and a second field isolation layer pattern in the second area, wherein the first field isolation layer pattern has a height smaller that the height of the first active structure.

20. The method of claim 13, wherein forming the second transistor comprises:
forming a second gate insulation layer on the second active structure;
forming a second conductive layer on the second gate insulation layer; and
etching the second conductive layer and the second gate insulation layer.
